(19) United States
(12) Patent Application Publication
(10) Pub. No.: US 2025/0112616 A1
(43) Pub. Date: Apr. 3, 2025

(54) ASYMMETRIC RESONATOR STACK FOR HIGH ELECTROMECHANICAL COUPLING

(71) Applicant: MACOM Technology Solutions Holdings, Inc., Lowell, MA (US)

(72) Inventors: Sahana KENCHAPPA, Lowell, MA (US); Mihir S. PATEL, Lowell, MA (US); Doug CARLSON, Lowell, MA (US); Rathnait LONG, Lowell, MA (US)

(21) Appl. No.: 18/480,336

(22) Filed: Oct. 3, 2023

(51) Int. Cl. H03H 9/13; H03H 9/02

(52) U.S. Cl. CPC H03H 9/13; H03H 9/02031

(57) ABSTRACT

Resonators and devices including resonators are described. An illustrative resonator includes a metal bottom electrode, a metal top electrode, and a piezoelectric layer positioned between the metal bottom electrode and the metal top electrode. At least one property of the metal bottom electrode may differ from at least one property of the metal top electrode such that the metal bottom electrode, the metal top electrode, and the piezoelectric layer provide a resonator target frequency as if the metal top electrode and metal bottom electrode were symmetrically configured, but provide a higher electromechanical coupling coefficient (kt2) as compared to a symmetrical configuration of the metal bottom electrode and the metal top electrode.

### FIELD OF THE DISCLOSURE

The present disclosure is generally directed toward resonators and devices incorporating the same.

### BACKGROUND

Acoustic resonators can be used to implement signal processing functions in various electronic applications. For example, some cellular phones and other communication devices use acoustic resonators to implement frequency filters for transmitted and/or received signals. Other examples of devices that incorporate resonators include medical devices, industrial devices, network devices, optical devices, etc. Resonators may also be included in filters of other devices for filtering noise or unwanted signals. Resonators may also be used in sensors, such as temperature sensors, pressure sensors, gyro sensors, and biometric sensors.

Several different types of acoustic resonators can be used according to different applications, with examples including bulk acoustic wave (BAW) resonators such as thin film bulk acoustic resonators (FBARs), stacked bulk acoustic resonators (SBARs), coupled resonator filters (CRFs), double bulk acoustic resonators (DBARs), and solidly mounted resonators (SMRs).

A typical acoustic resonator comprises a layer of piezoelectric material sandwiched between two plate electrodes in a structure referred to as an acoustic stack. Where an input electrical signal is applied between the electrodes, reciprocal or inverse piezoelectric effect causes the acoustic stack to mechanically expand or contract depending on the polarization of the piezoelectric material. As the input electrical signal varies over time, expansion and contraction of the acoustic stack produces acoustic waves (or modes) that propagate through the acoustic resonator in various directions and are converted into an output electrical signal by the piezoelectric effect. Some of the acoustic waves achieve resonance across the acoustic stack, with the resonant frequency being determined by factors such as the materials, dimensions, and operating conditions of the acoustic stack. These and other mechanical characteristics of the acoustic resonator determine its frequency response.

BAW resonators normally include a piezoelectric material sandwiched between two conducting metal electrodes, which is referred to as an acoustic stack. The acoustic stack is excited to generate standing acoustic wave resonance/s under applied electric field.

A resonator commonly has a series resonance frequency Fs and a parallel resonance frequency Fp. The distance of separation in frequency between Fs and Fp is a measure of the electromechanical coupling strength kt2. Resonators also include a quality (Q) factor. Resonators having a high electromechanical coupling coefficient kt2 are considered to provide better performance than resonators having a lower electromechanical coupling coefficient.

Generally speaking, the performance of a resonator can be evaluated by the values of its parallel resistance Rp, series resistance Rs, Q factor, and its electromechanical coupling coefficient kt2. The series resistance Rs is the smallest value of magnitude of input impedance of the acoustic resonator, and series resonance frequency Fs is a frequency at which that minimum occurs. The parallel resistance Rp is the largest value of magnitude of input impedance of the acoustic resonator, and parallel resonance frequency Fp is a frequency at which that maximum occurs. The Q factor is a parameter that quantifies the amount of energy lost in one cycle of oscillations. The electromechanical coupling coefficient kt2 is a normalized difference between parallel and series resonance frequencies Fp and Fs and is typically expressed in percent values (%).

Improvements in resonator performance translate to subsequent device performance for all possible different applications such as filters, sensors, and oscillators.

### SUMMARY

Embodiments of the present disclosure are contemplated to provide an improved resonator construction and devices incorporating the same. More specifically, embodiments of the present disclosure contemplate modification of a symmetric acoustic stack configuration to an asymmetric acoustic stack configuration. The asymmetric acoustic stack configurations depicted and described herein are designed to achieve a higher electromechanical coupling coefficient kt2 while providing the same (or substantially similar) resonator target frequency and resonator area as a symmetric acoustic stack configuration.

In some embodiments, an asymmetric resonator is provided that includes: a metal bottom electrode; a metal top electrode; and a piezoelectric layer positioned between the metal bottom electrode and the metal top electrode, wherein at least one property of the metal bottom electrode differs from at least one property of the metal top electrode, and wherein the metal bottom electrode, the metal top electrode, and the piezoelectric layer provide a resonator target frequency as if the metal top electrode and metal bottom electrode were symmetrically configured, but provide a higher electromechanical coupling coefficient (kt2) as compared to a symmetrical configuration of the metal bottom electrode and the metal top electrode.

In some embodiments, a device is provided that includes: a seed layer; a metal bottom electrode positioned adjacent to the seed layer; a piezoelectric layer positioned adjacent to the metal bottom electrode; and a metal top electrode positioned adjacent to the piezoelectric layer, wherein at least one property of the metal bottom electrode differs from at least one property of the metal top electrode, and wherein the metal bottom electrode, the metal top electrode, and the piezoelectric layer provide a resonator target frequency as if the metal top electrode and metal bottom electrode were symmetrically configured, but provide a higher electromechanical coupling coefficient (kt2) as compared to a symmetrical configuration of the metal bottom electrode and the metal top electrode.

In some embodiments, an acoustic wave resonator is provided that includes: a metal bottom electrode having a first thickness; a piezoelectric layer positioned adjacent to the metal bottom electrode; and a metal top electrode having a second thickness and being positioned adjacent to the piezoelectric layer such that the piezoelectric layer resides between the metal bottom electrode and the metal top electrode, wherein the second thickness is different from the first thickness.

The preceding is a simplified summary to provide a basic understanding of some aspects and embodiments described herein. This summary is not an extensive overview of the disclosed subject matter. It is neither intended to identify key nor critical elements of the disclosure nor delineate the scope thereof. The summary is provided to present some concepts in a simplified form as a prelude to the more detailed description that is presented later.

### BRIEF DESCRIPTION OF THE DRAWINGS

The present disclosure is described in conjunction with the appended figures, which are not necessarily drawn to scale:

FIG. 1 is a cross-sectional view illustrating a resonator having a symmetric configuration according to at least some embodiments of the present disclosure;

FIG. 2A is a cross-sectional view illustrating a resonator having a first asymmetric configuration according to at least some embodiments of the present disclosure;

FIG. 2B is a cross-sectional view illustrating a resonator having a second asymmetric configuration according to at least some embodiments of the present disclosure;

FIG. 2C is a cross-sectional view illustrating a resonator having a third asymmetric configuration according to at least some embodiments of the present disclosure;

FIG. 3A illustrates a frequency response curve for a resonator having a symmetric configuration according to at least some embodiments of the present disclosure;

FIG. 3B illustrates a frequency response curve for a resonator having an asymmetric configuration according to at least some embodiments of the present disclosure; and

FIG. 4 is a flow diagram depicting a method of designing and constructing an asymmetric resonator in accordance with embodiments of the present disclosure.

### DETAILED DESCRIPTION

Various aspects of the present disclosure will be described herein with reference to drawings that are schematic illustrations of idealized configurations. It should be appreciated that while particular circuit configurations and circuit elements are described herein, embodiments of the present disclosure are not limited to the illustrative circuit configurations and/or circuit elements depicted and described herein. Specifically, it should be appreciated that circuit elements of a particular type or function may be replaced with one or multiple other circuit elements to achieve a similar function without departing from the scope of the present disclosure.

The terms ‘a’, ‘an’ and ‘the’ include both singular and plural referents, unless the context clearly dictates otherwise. Thus, for example, ‘a device’ includes one device and plural devices. The terms ‘substantial’ or ‘substantially’ mean to within acceptable limits or degree. The term ‘approximately’ means to within an acceptable limit or amount to one of ordinary skill in the art. Relative terms, such as “above,” “below,” “top,” “bottom,” “upper” and “lower” may be used to describe the various elements' relationships to one another, as illustrated in the accompanying drawings. These relative terms are intended to encompass different orientations of the device and/or elements in addition to the orientation depicted in the drawings. For example, if the device were inverted with respect to the view in the drawings, an element described as “above” another element, for example, would now be below that element.

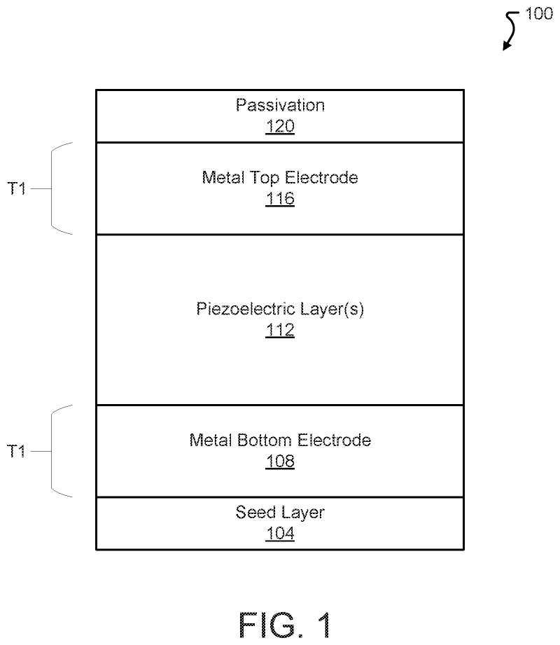

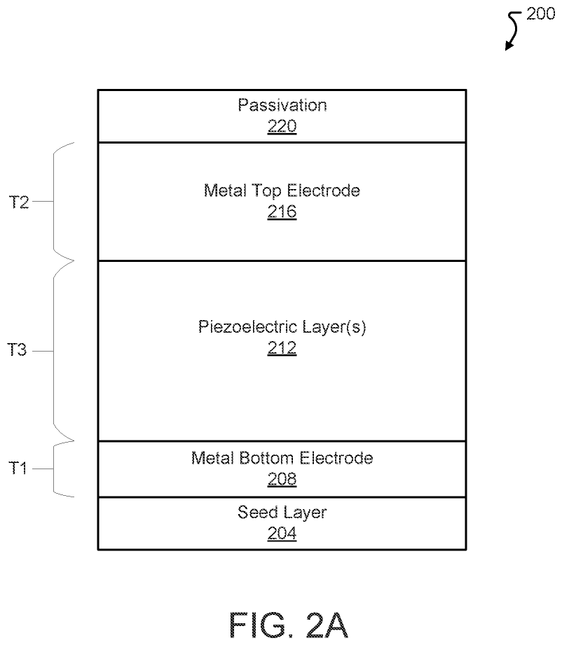

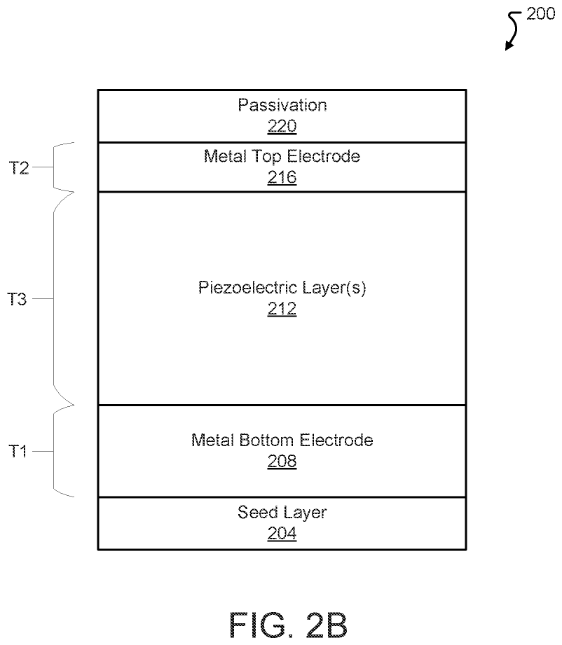

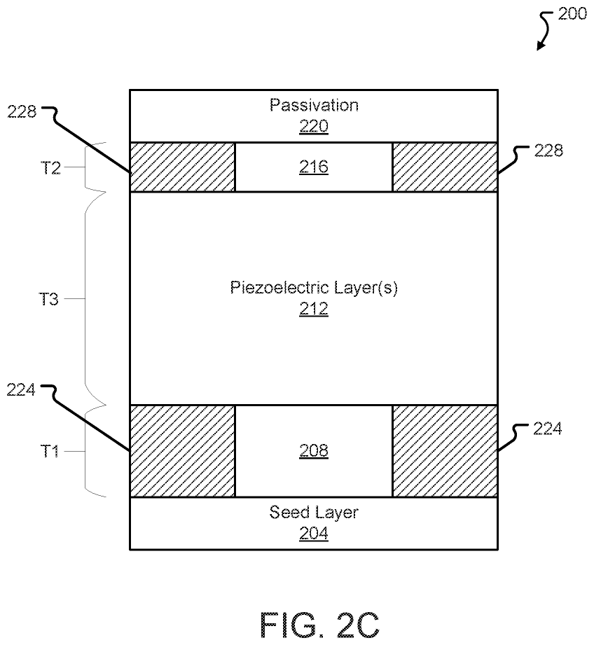

With reference now to FIGS. 1-2C, various configurations of a resonator will be described in accordance with at least some embodiments of the present disclosure. Referring initially to FIG. 1, a symmetric resonator 100 configuration will be described in accordance with at least some embodiments of the present disclosure. The symmetric resonator 100 is illustrated to include a seed layer 104, a metal bottom electrode 108, one or more piezoelectric layers 112, a metal top electrode 116, and a passivation layer 120.

In the illustrated configuration, and without limitation, the top surface of the seed layer 104 directly contacts the bottom surface of the metal bottom electrode 108. The top surface of the metal bottom electrode 108 directly contacts the bottom surface of the piezoelectric layer(s) 112. The top surface of the piezoelectric layer(s) 112 directly contacts the metal top electrode 116. The top surface of the metal top electrode 116 directly contacts the passivation layer 120.

In some embodiments, the seed layer 104 may comprise any material suitable for deposition the material of the metal bottom electrode 108 thereon. Illustratively, and without limitation, the seed layer 104 may be constructed of AlN, silicon carbide (SiC), silicon nitride SiC), aluminum oxide (Al203), and boron-doped silicon oxide. The seed layer 104 may be configured to foster growth of Al₁₋ₓScₓN.

The bottom metal electrode 108 and top metal electrode 116 of the symmetric resonator 100 may comprise substantially the same material and be formed to substantially the same thickness as one another. Examples of materials that may be used to form the bottom metal electrode 108 and/or top metal electrode 116 include, without limitation, molybdenum (Mo), niobium (Nb), aluminum (Al), platinum (Pt), ruthenium (Ru), and/or hafnium (Hf).

As illustrated in FIG. 1, the symmetric resonator 100 may include a metal bottom electrode 108 and metal top electrode 116 of the same thickness T1. It should be appreciated that the material selected for the metal electrodes 108, 116 and the thickness T1 may be selected to achieve a desired resonance frequency and electromechanical coupling coefficient kt2.

The piezoelectric layer(s) 112 may include one or multiple types of materials. In some embodiments, the piezoelectric layer(s) 112 include a single bulk layer of piezoelectric material. Example materials that may be used for the piezoelectric layer(s) 112 include, without limitation, AlN, Al₁₋ₓScₓN, or zinc oxide (ZnO).

The passivation layer 120 may be constructed of a material similar to the piezoelectric layer(s) 112. Illustratively, and without limitation, the passivation layer 120 may be constructed of AlN, SiC, non-etchable boron-doped silicon glass (NEBSG), SiO2, silicon nitride (SiN), polysilicon, and the like. The thickness of the passivation layer 120 should generally be sufficient to protect the layers of symmetric resonator 100 from chemical reactions with substances that may enter through a leak in a package.

Referring now to FIGS. 2A-2C, various configurations of asymmetric resonators 200 will be described in accordance with at least some embodiments of the present disclosure. Each of the asymmetric resonators 200 depicted and described herein may exhibit similar frequency responses to symmetric resonators 100 having similar overall thicknesses, but the asymmetric resonators 200 depicted and described herein may exhibit improved electromechanical coupling coefficients kt2 as compared to their symmetric counterparts.

Referring initially to FIG. 2A, the asymmetric resonator 200 is illustrated to include a seed layer 204, a metal bottom electrode 208, one or more piezoelectric layers 212, a metal top electrode 216, and a passivation layer 220. The seed layer 204 may be similar or identical to the seed layer 104. The passivation layer 220 may be similar or identical to the passivation layer 120.

The combination of the metal bottom electrode 208, piezoelectric layer(s) 212, and metal top electrode 216 may be similar in construction and/or functionality to the metal bottom electrode 108, piezoelectric layer(s) 112, and metal top electrode 116, respectively. The layers 208, 212, 216 may be different from layers 108, 112, 116, however, in that they construction of layers 208, 212, 216 may be asymmetric. More specifically, and without limitation, at least one property of the metal bottom electrode 208 differs from at least one property of the metal top electrode 216. Examples of properties that may differ between the metal bottom electrode 208 and metal top electrode 216 include, without limitation, thickness properties, material properties, construction properties, or the like. In some embodiments, the metal bottom electrode 208, the metal top electrode 216, and the one or more piezoelectric layers 212 provide a resonator target frequency similar to the top metal electrode 116 and bottom metal electrode 108 of the symmetrical resonator 100. However, the asymmetric configuration of the metal bottom electrode 208 and the metal top electrode 216 provide a higher electromechanical coupling coefficient kt2 as compared to a symmetrical configuration of the metal bottom electrode 108 and the metal top electrode 116. Asymmetries of the resonator 200 may be realized in a number of different ways.

In the example of FIG. 2A, the metal bottom electrode 208 comprises a first thickness T1 and the metal top electrode 216 comprises a second thickness T2 that is different from the first thickness T1. In some embodiments, the combined thicknesses of the metal bottom electrode 208 (e.g., T1), the piezoelectric layer(s) 212 (e.g., T3), and the metal top electrode 216 (e.g., T2) may be equal to the combined thickness of the metal bottom electrode 108, the piezoelectric layer(s) 112, and the metal top electrode 116. However, because the acoustic stack 208, 212, 216 is configured asymmetrically, the asymmetric resonator 200 may provide an improved electromechanical coupling coefficient kt2 as compared to the symmetric resonator 100. The configuration of the resonator 200 in FIG. 2A illustrates a configuration where the thickness properties of the metal bottom electrode 208 and the metal top electrode 216 are different.

Referring now to FIG. 2B, a different configuration of the asymmetric resonator 200 is illustrated. The configuration of the resonator 200 in FIG. 2B exhibits a configuration where the thickness property of the metal bottom electrode 208 is different from the thickness of the metal top electrode 216. This configuration as compared to the configuration of FIG. 2A exhibits a configuration where the first thickness T1 of the metal bottom electrode 208 is greater than the second thickness T2 of the metal top electrode 216. The third thickness T3 of the piezoelectric layer(s) 212 may be similar or identical to the third thickness T3 of the piezoelectric layer(s) 212 illustrated in FIG. 2A.

Much like the configuration of FIG. 2A, the configuration of the asymmetric resonator 200 in FIG. 2B may have similar resonance frequencies as the symmetric resonator 100, but the electromechanical coupling coefficient kt2 of the asymmetric resonator 200 is greater than the electromechanical coupling coefficient kt2 of the symmetric resonator 100.

In addition to the differing thickness properties exhibited in FIGS. 2A and 2B (or as an alternative thereto), the asymmetric resonator 200 may provide metal electrodes having different material properties and/or construction properties. As an example, the metal bottom electrode 208 may include at least one material that is not included in the metal top electrode 216. Likewise, the metal top electrode 216 may include at least one material that is not included in the metal bottom electrode 208. In other words, at least one material property of the metal bottom electrode 208 may be different from at least one material property of the metal top electrode 216.

Referring now to FIG. 2C, another possible configuration of an asymmetric resonator 200 is illustrated in accordance with at least some embodiments of the present disclosure. The metal bottom electrode 208 may include a different construction property from the metal top electrode 216. In addition to or in substitution of having different thickness properties, the metal bottom electrode 208 may be constructed differently from the metal top electrode 216. In the illustrative embodiment, the metal bottom electrode 208 is shown to include a first grid 224 of material while the metal top electrode 216 is shown to include a second grid 228. Materials of the first grid 224 may be different from the second grid 228. Alternatively or additionally, the layout of the first grid 224 within the metal bottom electrode 208 may be different from the layout of the second grid 228 within the metal top electrode 216. Materials used for the grid 224 and/or grid 228 may be different from the materials used in the metal bottom electrode 208 and/or the metal top electrode 216.

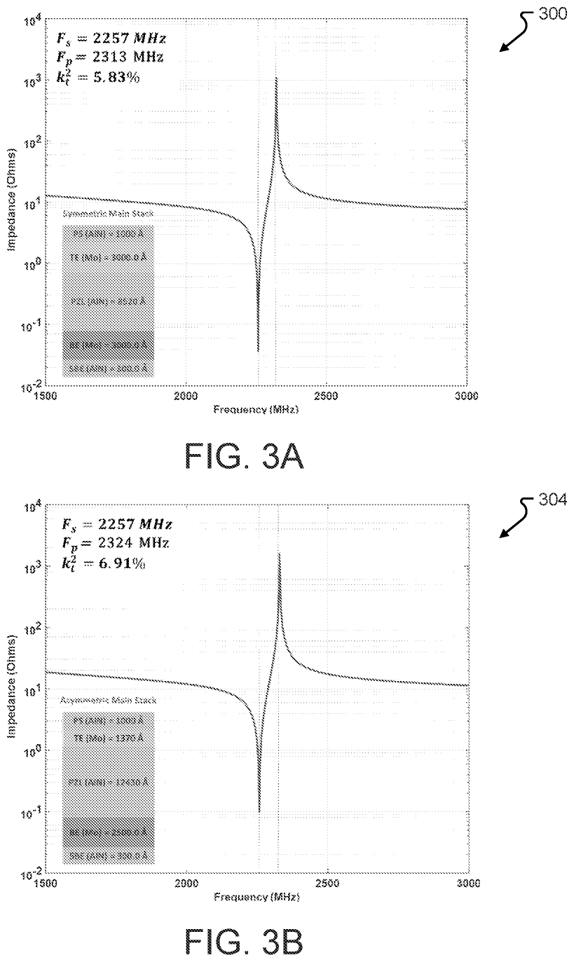

Referring now to FIGS. 3A and 3B, the performance of a symmetric resonator 100 as compared to an asymmetric resonator 200 is depicted. More specifically, FIG. 3A illustrates a frequency response for a symmetric resonator 100 whereas FIG. 3B illustrates a frequency response for an asymmetric resonator 200. It should be appreciated that the frequency response for the asymmetric resonator 200 corresponds to a non-limiting example of a frequency response for a non-limiting example of an asymmetric resonator 200 having a particular configuration. Embodiments of the present disclosure are not intended to be limited to the particular configuration of the asymmetric resonator 200 that resulted in the frequency response illustrated in FIG. 3B.

The frequency response 300 of FIG. 3A corresponds to a symmetric resonator 100 having a total thickness of 15820 Å whereas the frequency response 304 of FIG. 3B corresponds to an asymmetric resonator 200 having a total thickness of 16600 Å. Both frequency responses exhibit a series resonance frequency Fs of 2257 MHz. The symmetric stack frequency response exhibits a parallel resonance frequency Fp of 2313 MHz whereas the asymmetric stack frequency response exhibits a parallel resonance frequency Fp of 2324 MHz. Both resonators 100, 200 exhibits a resonator area of 46777 um². A significant difference between the performance of the asymmetric resonator 200 as compared to the symmetric resonator 100 is that the asymmetric resonator 200 exhibits an electromechanical coupling coefficient kt2 of 6.91% as compared to the electromechanical coupling coefficient kt2 of 5.83% exhibited by the symmetric resonator 100.

An examination of dispersion curves for the symmetric resonator 100 as compared to the asymmetric resonator 200 reveal that a lower attenuation is achieved for the asymmetric resonator 200. This enables the asymmetric resonator 200 to perform better as compared to the symmetric resonator 100.

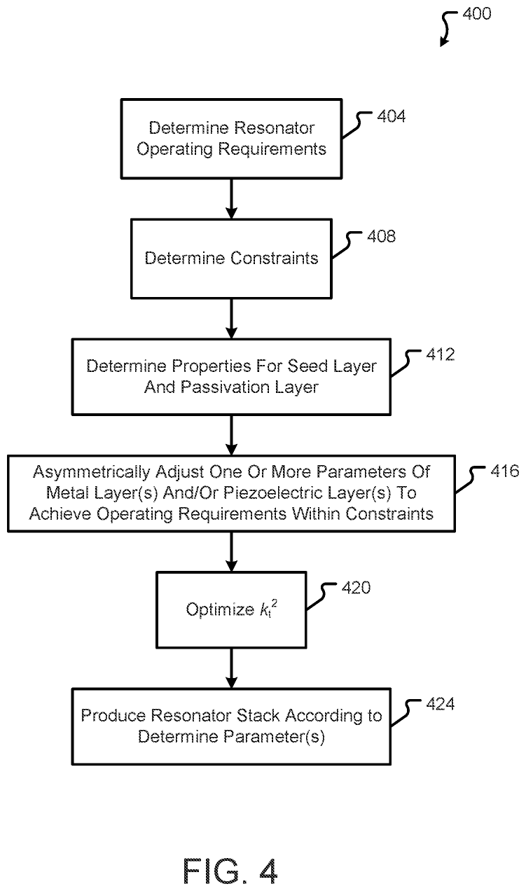

Referring now to FIG. 4, a method 400 will be described in accordance with at least some embodiments of the present disclosure. The method 400 begins by determining resonator operating requirements (step 404). Resonator operating requirements may include kt2 requirements, Q factor requirements, resonance frequency requirements, thickness requirements, resonator area requirements, and the like.

The method 400 continues by determining constraints for the resonator (step 408). Resonator constraints may include material constraints, layer property constraints, thickness constraints, frequency constraints, kt2 constraints, Q factor constraints, and the like.

The method 400 further continues by determining properties for the seed layer 204 and passivation layer 220 (step 412). Properties determined for the seed layer 204 and passivation layer 220 may depend on the application the resonator, desired materials for the acoustic stack 208, 212, 216, and the like.

The method 400 then proceed by asymmetrically adjusting one or more parameters of the metal layer(s) 208, 216 and/or the piezoelectric layer(s) 212 to achieve the operating requirements within the determined constraints (step 416). In some embodiments, the thicknesses and/or material properties of the metal layers 208, 216 may be adjusted asymmetrically to improve and possibly optimize kt2 (step 420) for the resonator 200 while facilitating other operating requirements, such as resonance frequency, within determined constraints, such as total thickness.

Once the properties of the metal layers 208, 216 and the piezoelectric layer(s) 212 have been determined, the method 400 may continue by producing the resonator 200 according to the determined parameter(s) (step 424). The resonator 200 may be produced using bulk production methodologies, film deposition methodologies, vapor deposition methodologies, combinations thereof, and the like.

Specific details were given in the description to provide a thorough understanding of the embodiments. However, it will be understood by one of ordinary skill in the art that the embodiments may be practiced without these specific details. In other instances, well-known circuits, processes, algorithms, structures, and techniques may be shown without unnecessary detail in order to avoid obscuring the embodiments.

While illustrative embodiments of the disclosure have been described in detail herein, it is to be understood that the inventive concepts may be otherwise variously embodied and employed, and that the appended claims are intended to be construed to include such variations, except as limited by the prior art.

What is claimed is:

1. An asymmetric resonator stack, comprising:
a metal bottom electrode;
a metal top electrode; and
a piezoelectric layer positioned between the metal bottom electrode and the metal top electrode, wherein at least one property of the metal bottom electrode differs from at least one property of the metal top electrode, and wherein the metal bottom electrode, the metal top electrode, and the piezoelectric layer provide a resonator target frequency as if the metal top electrode and metal bottom electrode were symmetrically configured, but provide a higher electromechanical coupling coefficient (kt2) as compared to a symmetrical configuration of the metal bottom electrode and the metal top electrode.

2. The asymmetric resonator stack of claim 1, further comprising:
a seed layer, wherein the metal bottom electrode is positioned between the piezoelectric layer and the seed layer.

3. The asymmetric resonator stack of claim 2, further comprising:
a passivation layer, wherein the metal top electrode is positioned between the piezoelectric layer and the passivation layer.

4. The asymmetric resonator stack of claim 3, wherein the piezoelectric layer comprises a plurality of piezoelectric layers.

5. The asymmetric resonator stack of claim 3, wherein the piezoelectric layer comprises a bulk piezoelectric layer.

6. The asymmetric resonator stack of claim 1, wherein the metal bottom electrode and the metal top electrode comprise molybdenum and wherein a thickness property of the metal bottom electrode is different from a thickness property of the metal top electrode.

7. The asymmetric resonator stack of claim 1, wherein the piezoelectric layer comprises at least one of Aluminum Nitride (AlN) and Aluminum Scandium Nitride (ScAlN).

8. The asymmetric resonator stack of claim 1, wherein a material property of the metal bottom electrode is different from a material property of the metal top electrode.

9. The asymmetric resonator stack of claim 1, wherein at least one of the metal bottom electrode and the metal top electrode comprise multiple materials formed in a grid.

10. The asymmetric resonator stack of claim 9, wherein both the metal bottom electrode and the metal top electrode comprise the grid.

11. A device, comprising:
a seed layer;
a metal bottom electrode positioned adjacent to the seed layer;
a piezoelectric layer positioned adjacent to the metal bottom electrode; and
a metal top electrode positioned adjacent to the piezoelectric layer, wherein at least one property of the metal bottom electrode differs from at least one property of the metal top electrode, and wherein the metal bottom electrode, the metal top electrode, and the piezoelectric layer provides a resonator target frequency as if the metal top electrode and metal bottom electrode were symmetrically configured, but provide a higher electromechanical coupling coefficient (kt2) as compared to a symmetrical configuration of the metal bottom electrode and the metal top electrode.

12. The device of claim 11, further comprising:
a passivation layer, wherein the metal top electrode is positioned between the piezoelectric layer and the passivation layer.

13. The device of claim 11, wherein a thickness property of the metal bottom electrode is different from a thickness property of the metal top electrode.

14. The device of claim 13, wherein the metal top electrode comprises a thickness that is less than a thickness of the metal top electrode.

15. The device of claim 13, wherein the metal top electrode comprises a thickness that is greater than a thickness of the metal top electrode.

16. The device of claim 13, wherein the metal top electrode comprises a thickness that is less than a thickness of the metal top electrode.

17. The device of claim 11, wherein the piezoelectric layer directly contacts the metal bottom electrode and the metal top electrode.

18. An acoustic wave resonator, comprising:
a metal bottom electrode having a first thickness;
a piezoelectric layer positioned adjacent to the metal bottom electrode; and
a metal top electrode having a second thickness and being positioned adjacent to the piezoelectric layer such that the piezoelectric layer resides between the metal bottom electrode and the metal top electrode, wherein the second thickness is different from the first thickness.

19. The acoustic wave resonator of claim 18, wherein a material property of the metal bottom electrode is different from a material property of the metal top electrode.

20. The acoustic wave resonator of claim 18, wherein the metal bottom electrode is thicker than the metal top electrode.
